(19) United States
(12) Patent Application Publication
(10) Pub. No.: US 2025/0167147 A1
(43) Pub. Date: May 22, 2025

(54) SEMICONDUCTOR PACKAGE AND METHOD FOR MANUFACTURING THE SAME

(71) Applicant: Samsung Electronics Co., Ltd., Suwon-si (KR)

(72) Inventor: JAESIC LEE, Suwon-si (KR)

(21) Appl. No.: 18/747,852

(22) Filed: Jun. 19, 2024

(30) Foreign Application Priority Data
Nov. 16, 2023 (KR) 10-2023-0159191

(51) Int. Cl. H01L 23/00; H01L 23/48; H01L 23/522; H01L 25/10; H10B 80/00

(52) U.S. Cl. CPC H01L 24/05; H01L 23/481; H01L 24/03; H01L 24/06; H01L 24/08; H01L 24/09; H01L 25/105; H01L 23/522; H01L 2224/03845; H01L 2224/05556; H01L 2224/06051; H01L 2224/06181; H01L 2224/08146; H01L 2224/09055; H01L 2224/09181; H01L 2225/1011; H10B 80/00

(57) ABSTRACT

A semiconductor package according to an embodiment includes a first semiconductor die including a back side bonding structure; and a second semiconductor die including a front side bonding structure bonded to the back side bonding structure, wherein the back side bonding structure includes a first dielectric layer; and first bonding pads passing through the first dielectric layer, the front side bonding structure includes a second dielectric layer bonded to the first dielectric layer; and second bonding pads with each second bonding pad bonded to a respective first bonding pad and passing through the second dielectric layer, and the first dielectric layer includes oblique edge portions around the first bonding pads at the surface facing the second dielectric layer.

### CROSS-REFERENCE TO RELATED APPLICATION

This application claims priority to and the benefit of Korean Patent Application No. 10-2023-0159191 filed in the Korean Intellectual Property Office on Nov. 16, 2023, and all the benefits accruing therefrom under 35 U.S.C. 119, the entire contents of which are incorporated herein by reference.

### BACKGROUND OF THE INVENTION

### (a) Field of the Invention

The present disclosure relates to a semiconductor package and a method for manufacturing the same.

### (b) Description of the Related Art

As the semiconductor industry pursues higher speed, increased multi-functionality, and larger capacity for a semiconductor devices while simultaneously down-sizing, lightweight, and thinner semiconductor packages mounted on electronic devices are being developed in response to the down-sizing and lightweight requirements for the electronic devices. Therefore, a packaging technology that can store more data and transmit data with faster speeds is beneficial. As such a packaging technology, a stacked semiconductor device (e.g., a high bandwidth memory (HBM)), which is formed by stacking individual semiconductor chips, is being developed.

The stacked semiconductor devices may be manufactured by combining the same type or different type semiconductor chips. What is important in combining the semiconductor chips is that the semiconductor chips are combined with high I/O density. If the I/O density is increased and an electric signal connection density becomes similar to a copper line density in the semiconductor front end process, even if same type or different type of semiconductor chips are combined in a semiconductor back end process, results similar to a single semiconductor chip made through the semiconductor front end process may be produced.

In order to manufacture the stacked semiconductor devices with high I/O density, a hybrid bonding process may be applied to form a bond between semiconductor chips of the stacked semiconductor devices. Hybrid bonding is a method of bonding two devices together by fusing the same materials of two devices together using the bonding properties of the same materials. For example, bonding two devices may be implemented with a bonding between metal-metal as a first type of bond and bonding the two devices with a bonding between nonmetal-nonmetal as a second type of bond. This may be referred to as hybrid bonding.

The hybrid bonding should be performed in a state in which each bonding surface of the semiconductor chips is flat. However, if the hybrid bonding is performed in a state where each bonding surface of the semiconductor chips is not flat due to a surface topography deviation, or process technology problems, the vertical lines of the bonding surfaces of bonding pads are not aligned.

Due to the discrepancy in the vertical lines of the bonding surfaces of the bonding pads, each bonding surface of the bonding pads that are misaligned may come into contact with the dielectric layer, and the contacted bonding pad and the dielectric layer are not bonded to each other, which may cause cracks. Additionally, during the bonding process, the edge of the dielectric layer may be broken due to a contact impact between the edge of the dielectric layer and the bonding pad.

Therefore, the development of a new semiconductor package technology that may improve this problem is necessary.

### SUMMARY OF THE INVENTION

In a semiconductor structure including a bonding structure for performing a hybrid bonding, a bonding structure includes bonding pads with a rounded side shape and a dielectric layer including edge portions chamfered around the bonding pads.

A semiconductor package according to an embodiment may include a first semiconductor die including a back side bonding structure; and a second semiconductor die including a front side bonding structure bonded to the back side bonding structure, wherein the back side bonding structure includes a first dielectric layer; and first bonding pads passing through the first dielectric layer, the front side bonding structure includes a second dielectric layer bonded to the first dielectric layer; and second bonding pads with each second bonding pad bonded to a respective first bonding pads and passing through the second dielectric layer, and wherein the first dielectric layer includes oblique edge portions around the first bonding pads at a surface facing the second dielectric layer.

A semiconductor package according to an embodiment may include a first semiconductor die and a second semiconductor die, wherein the first semiconductor die includes a first substrate; through silicon vias extending from a front side of the first substrate to a back side of the first substrate; and a back side bonding structure positioned on the back of the first substrate, the second semiconductor die includes a second substrate; a wire layer positioned on the front side of the second substrate; and a front side bonding structure positioned on the wire layer and bonded to the back side bonding structure, the back side bonding structure includes a first dielectric layer; and first bonding pads passing through the first dielectric layer, wherein each first bonding pad of the first bonding pads is in contact with a through silicon via among the through silicon vias, and the front side bonding structure includes a second dielectric layer bonded to the first dielectric layer; and second bonding pads with each second bonding pad bonded to a respective first bonding pad and passing through the second dielectric layer, and wherein the first dielectric layer includes oblique edge portions around the first bonding pads at a surface facing the second dielectric layer.

A manufacturing method of a semiconductor package according to an embodiment may include forming through silicon vias within a semiconductor die, wherein the through silicon vias extend from a front side to a back side of the substrate of the semiconductor die; forming ball-shaped bonding pads in the first ends of the through silicon vias; exposing the bonding pads by etching the back side surface of the substrate; forming a first dielectric layer on the exposed bonding pads and the etched back side of the substrate; performing a planarization process on the bonding pads and the first dielectric layer; forming a second dielectric layer on the planarized first bonding pads and the first dielectric layer; forming a pattern on the second dielectric layer exposing an upper surface of the planarized first bonding pads; and etching the pattern of the second dielectric layer and performing a chamfering process on the first dielectric layer around the first bonding pads

In the semiconductor structure including the bonding structure for performing hybrid bonding, the bonding structure may include the bonding pads having a rounded side shape; and the dielectric layer having edge portions chamfered around the bonding pads.

With this shape of the bonding pads and the dielectric layer, a space may be provided between the edge of the dielectric layer and the bonding pads to prevent the dielectric layer and the bonding pads from contacting each other. As a result, during the bonding process, the edge of the dielectric layer is prevented from being broken due to contact and impact between the edge of the dielectric layer and the bonding pad, and reliability may be improved.

Additionally, the process of forming the bonding pads with the rounded side shape may be performed in the semiconductor front end process with fewer steps than when forming the bonding pads in the semiconductor back end process. As a result, the process of forming the bonding pads may be omitted from the semiconductor back end process, thereby reducing a turn around time (TAT) and a process complexity, and reducing manufacturing costs.

### BRIEF DESCRIPTION OF THE DRAWINGS

FIG. 1 is a cross-sectional view of a first semiconductor die according to an embodiment.

FIG. 2 is a cross-sectional view showing a region B of a first semiconductor die of FIG. 1.

FIG. 3 is a cross-sectional view showing a first semiconductor stacking structure according to an embodiment.

FIG. 4 is a cross-sectional view showing a region C of an embodiment in a first semiconductor stacking structure of FIG. 3.

FIG. 5 is a cross-sectional view showing a region C of another embodiment in a first semiconductor stacking structure of FIG. 3.

FIG. 6 is a cross-sectional view showing a semiconductor package of an embodiment.

FIG. 7 is a cross-sectional view showing a second semiconductor stacking structure of another embodiment.

FIG. 8 is a cross-sectional view showing a semiconductor package according to another embodiment.

FIG. 9 to FIG. 18 are cross-sectional views to explain a method of manufacturing a first semiconductor die of FIG. 1.

### DETAILED DESCRIPTION OF THE EMBODIMENTS

Hereinafter, embodiments of the present invention will be described in detail so that a person of an ordinary skill in the technical field to which the present invention belongs can easily implement. As those skilled in the art would realize, the described embodiments may be modified in various different ways, all without departing from the spirit or scope of the present invention.

The same elements or equivalents may be referred to by the same reference numerals throughout the specification.

Further, since sizes and thicknesses of constituent members and their relation to one another as shown in the accompanying drawings may be exaggerated for better understanding and ease of description, the present invention is not limited to the relative sizes and thicknesses illustrated in the drawings. Though the different figures show variations of exemplary embodiments, these figures are not necessarily intended to be mutually exclusive from each other. Rather, as will be seen from the context of the detailed description below, certain features depicted and described in different figures can be combined with other features from other figures to result in various embodiments, when taking the figures and their description as a whole into consideration.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

Throughout the specification, when it is described that a part is “connected (in contact with, coupled)” to another part, the part may be “directly connected” to the other element or “connected” to the other part through an intervening part. In contrast, when an element is referred to as being “directly connected” or “directly coupled” to another element, or as “contacting” or “in contact with” another element (or using any form of the word “contact”), there are no intervening elements present at the point of contact. In addition, unless explicitly described to the contrary, the word “comprise”, and variations such as “comprises” or “comprising”, will be understood to imply the inclusion of stated elements but not the exclusion of any other elements.

As used herein, elements described as being “electrically connected” are configured such that an electrical signal can be passed from one element to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two device, an electrically insulative underfill or mold layer, etc.) is not electrically connected to that component. Moreover, elements that are “directly electrically connected,” to each other are electrically connected through one or more passive elements, such as, for example, wires, pads, internal electrical lines, through vias, etc. As such, directly electrically connected components do not include components electrically connected through active elements, such as transistors or diodes. Directly electrically connected elements may be directly physically connected and directly electrically connected.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” means positioned above or below the object portion and does not necessarily mean positioned on the upper side of the object portion based on a gravitational direction. Additionally, when using spatially relative terms, such as “beneath,” “below,” “lower,” “above,” “upper,” “top,” “bottom,” and the like, they are used herein for ease of description to describe positional relationships, such as illustrated in the figures, for example. It will be understood that the spatially relative terms encompass different orientations of the device in addition to the orientation depicted in the figures.

Further, in the specification, the phrase “on a plane” means when an object portion is viewed from above, and the phrase “on a cross-section” means a cross-section taken by a vertical cutting plane and an object portion is viewed from the side.

Hereinafter, a semiconductor package 11 including a first semiconductor die 100 and a second semiconductor die 200, a semiconductor package 21 including a third semiconductor die 300 and a fourth semiconductor die 400, and a method of manufacturing the first semiconductor die 100 according to an embodiment are described with reference to accompanying drawings.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

As used herein, the singular forms “a”, “an” and “the” are intended to include the plural forms as well, unless the context clearly indicates otherwise. Furthermore, relationship between plural elements may include one-to-one, one-to-many, and many-to-many relationships unless the otherwise specified or limited by the context of the relationship. As used herein, the term “and/or” includes any and all combinations of one or more of the associated listed items and may be abbreviated as “/”.

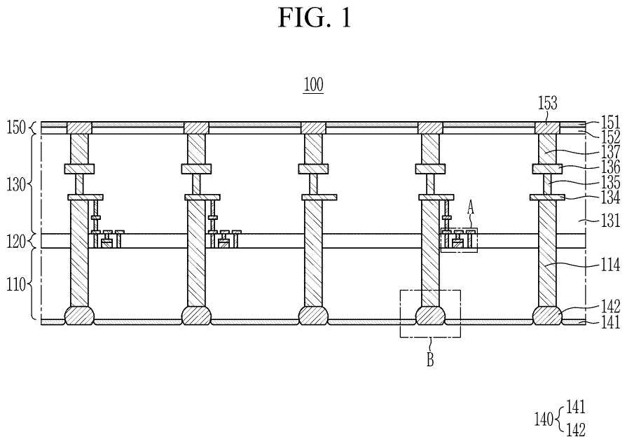

FIG. 1 is a cross-sectional view showing a first semiconductor die 100 of an embodiment.

Referring to FIG. 1, the first semiconductor die 100 includes a substrate 110, an activation layer 120, a wire layer 130, through silicon vias (TSV; 114), a first front side bonding structure 150, and a first back side bonding structure 140. The activation layer 120, the wire layer 130, and the first front side bonding structure 150 may be disposed on the front side of the substrate 110, and the first back side bonding structure 140 may be disposed on the back side of the substrate 110. The through silicon vias (TSV; 114) are disposed to pass through the substrate 110. In an embodiment, the first semiconductor die 100 may be a semiconductor die used in a semiconductor stacking structure such as a high bandwidth memory (HBM) or a 3D integrated circuit (3DIC).

The substrate 110 may be a die formed from a wafer. In an embodiment, the substrate 110 may be formed of and/or include silicon or another semiconductor material. In an embodiment, the substrate 110 May include an impurity doped well or an impurity doped structure. The substrate 110 may have various device isolation structures, such as a shallow trench isolation (STI) structure. In an embodiment, the substrate 110 may be and/or include bulk silicon, silicon-on-insulator (SOI) substrate, a silicon substrate, silicon germanium, a silicon germanium-on-insulator (SGOI) substrate, silicon carbide, indium antimony, a lead tellurium compound, indium arsenic, indium phosphide, gallium arsenic, or antimony gallium.

The activation layer 120 is positioned on the front side of the substrate 110. The activation layer 120 may be formed on the substrate 110 in a front-end-of-line (FEOL) process of the semiconductor front end process. The activation layer 120 includes an integrated circuit (IC) structure A having IC regions. In an embodiment, the IC structure A may include at least one of an active device or a passive device. In an embodiment, the IC structure A may include a gate structure, a source region, and a drain region. In an embodiment, the IC structure A may include at least one of a transistor, a diode, a capacitor, an inductor, or a resistor.

In an embodiment, the IC structure A may include at least one of a memory device or a logic device. The memory device may include a volatile memory element or a non-volatile memory device. In an embodiment, the volatile memory device may include a dynamic random access memory (DRAM), a static RAM (SRAM), a thyristor RAM (TRAM), a zero capacitor RAM (ZRAM), or a twin transistor RAM (TTRAM). In an embodiment, the non-volatile memory device may include a flash memory, a magnetic RAM (MRAM), a spin-transfer torque MRAM (STT-MRAM), a ferroelectric RAM (FRAM), a phase change RAM (PRAM), or a resistive RAM (RRAM), etc. In an embodiment, the logic device may include a microprocessor, a graphics processor, a signal processor, a network processor, or a codec.

The wire layer 130 may be positioned on the front side of the substrate 110. The wire layer 130 may be formed on the activation layer 120 in a back-end-of-line (BEOL) process of the semiconductor front side process. The wire layer 130 includes wire lines 134 and 136, contact plugs 135 and 137, and an inter metal dielectric (IMD; 131). The wire layer 130 may have multiple levels stacked in a direction normal to the front side of the substrate 110 with wire lines 134 in a first level and wire lines 136 in a second level.

The wire lines 134 and 136 and the contact plugs 135 and 137 may be signal wires that transmit signals between each device in a semiconductor die or between devices external to a semiconductor die, or electric power wires that transmit electric power to each device in the semiconductor die or to a device external to the semiconductor die. The wire lines 134 and 136 are patterned in the horizontal direction to transmit a signal and/or electric power in a level. The contact plugs 135 and 137 are patterned in the vertical direction to interconnect the wire lines 134 and 136 to transfer a signal and/or electric power between wire lines at different levels.

In an embodiment, the wire lines 134 and 136 and the contact plugs 135 and 137 may each be formed of and/or include at least one of copper, aluminum, tungsten, nickel, gold, tin, titanium, or alloys thereof. In other embodiments, the wire layer 130 may include fewer or more wire lines and contact plugs than shown in FIG. 1 and such embodiments are included in the scope of the present disclosure.

The inter metal dielectric material (IMD; 131) buries and insulates the wire lines 134 and 136 and the contact plugs 135 and 137. In an embodiment, the inter metal dielectric material (IMD; 131) may be formed of and/or include silicon oxide, silicon nitride, silicon oxynitride, oxide formed with TEOS, PSG, BPSG, low-k dielectric material, other suitable dielectric material, or combinations thereof.

The through silicon vias (TSV; 114) may extend from the front side to the back side of the substrate 110. The through silicon vias (TSV; 114) may be formed in the BEOL process of the semiconductor front end process. In an embodiment, the through silicon vias (TSV; 114) may extend from the inter metal dielectric material (IMD; 131) of the wire layer 130 into the substrate 110 through the activation layer 120. In another embodiment, the through silicon vias (TSV; 114) may extend from the activation layer 120 into the substrate 110. In an embodiment, a first end of the through silicon via (TSV; 114) may be connected to a first bonding pad 142 of the first back side bonding structure 140, and the second end of the through silicon via (TSV; 114) may be connected to a wire line 134 of the wire layer 130. In another embodiment, the second end of the through silicon via (TSV; 114) may be connected to a wire line of the activation layer 120.

The first back side bonding structure 140 is disposed on the back side of the substrate 110. The first back side bonding structure 140 includes a first dielectric layer 141 and first bonding pads 142. The first dielectric layer 141 may be formed in the semiconductor back end process. The first bonding pads 142 are formed in the BEOL process of the semiconductor front end process.

The first dielectric layer 141 is positioned on the back side of the substrate 110. The first dielectric layer 141 is a layer where the nonmetal-nonmetal hybrid bonding is performed with the dielectric layer of another semiconductor die. The first dielectric layer 141 includes openings in which the first bonding pads 142 may be disposed. An edge portion of each opening may be angled away from the opening. For example, the edge portion may have a chamfer, a fillet, angle edges, or other oblique edge around the first bonding pads 142. In an embodiment, the first dielectric layer 141 may be formed of and/or include silicon nitride. In an embodiment, the first dielectric layer 141 may be formed of and/or include SiN or SiCN. In an embodiment, the thickness of the first dielectric layer 141 in the vertical direction may be in the range of about 0.05 μm to about 1 μm.

The first bonding pads 142 positioned such that they pass through the first dielectric layer 141. The first bonding pads 142 are pads on which the metal-metal hybrid bonding is performed with bonding pads of other semiconductor dies, thereby establishing an electrical connection between the first back side bonding structure 140 and the other semiconductor die. The first bonding pads 142 are electrically connected with the through silicon vias 114. The level of the lower surfaces of the first bonding pads 142 may be at the same level as the level of the lower surface of the first dielectric layer 141. In an embodiment, the width of the first bonding pads 142 in the horizontal direction may be in the range of about 0.01 μm to about 30 μm. In an embodiment, the depth of the first bonding pads 142 in the vertical direction may be in the range of about 0.1 μm to about 7 μm. In an embodiment, the first bonding pads 142 may be formed of and/or include copper. In another embodiment, the first bonding pads 142 may be a metallic material capable of hybrid bonding.

The first front side bonding structure 150 is positioned at the front side of the substrate 110. The first front side bonding structure 150 may be positioned on the wire layer 130. The first front side bonding structure 150 includes a second dielectric layer 151, a third dielectric layer 152, and second bonding pads 153. The second dielectric layer 151, the third dielectric layer 152, and the second bonding pads 153 may be formed in the semiconductor back end process.

The second dielectric layer 151 is disposed on the front side of the substrate 110. The second dielectric layer 151 is a layer where the nonmetal-nonmetal hybrid bonding is performed with a dielectric layer of another semiconductor die. In an embodiment, the second dielectric layer 151 may be formed of and/or include silicon nitride. In an embodiment, the second dielectric layer 151 may be formed of and/or include SiN or SiCN. In an embodiment, the thickness of the second dielectric layer 151 in the vertical direction may be in the range of about 0.05 μm to about 1 μm.

The third dielectric layer 152 is positioned between the wire layer 130 and the second dielectric layer 151. In an embodiment, the third dielectric layer 152 may be formed of and/or include silicon oxide, oxide formed with TEOS, other suitable dielectric material, or a combination thereof. In an embodiment, the thickness of the third dielectric layer 152 in the vertical direction may be in the range of about 0.1 μm to about 7 μm.

The second bonding pads 153 pass through the second dielectric layer 151 and the third dielectric layer 152. The second bonding pads 153 are pads on which the metal-metal hybrid bonding is performed with the bonding pads of other semiconductor dies, thereby establishing an electrical connection between the first front side bonding structure 150 and the other semiconductor die. The second bonding pads 153 are electrically connected to the contact plugs 137 of the wire layer 130. The level of the upper surfaces of the second bonding pads 153 may be at the same level as the level of the upper surface of the second dielectric layer 151. The sides of the second bonding pads 153 are surrounded by the second dielectric layer 151 and the third dielectric layer 152. In an embodiment, the width of the second bonding pads 153 in the horizontal direction may be in the range of about 0.01 μm to about 30 μm. In an embodiment, the depth of the second bonding pads 153 in the vertical direction may be in the range of about 0.1 μm to about 7 μm. In an embodiment, the second bonding pads 153 may be formed of and/or include copper. In another embodiment, the second bonding pads 153 may be a conductive material capable of hybrid bonding.

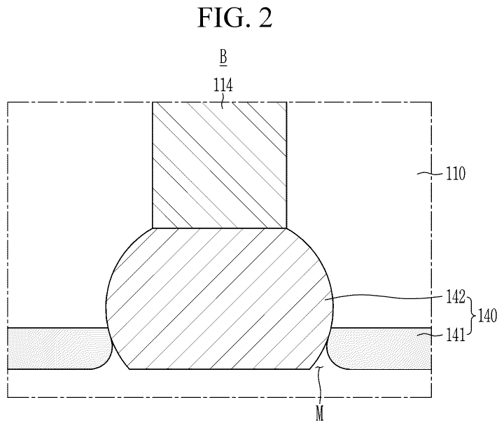

FIG. 2 is a cross-sectional view showing a region B of a first semiconductor die 100 in FIG. 1.

Referring to FIG. 2, the first back side bonding structure 140 includes the first dielectric layer 141 and the first bonding pads 142.

The first dielectric layer 141 includes openings having edge portions angled away (M) from the first bonding pads 142. For example, the edge portion may have a chamfer, a fillet, angle, or other oblique edge. The edge portion of the first dielectric layer 141 are spaced apart from the first bonding pad 142. In an embodiment, the edge portion of the first dielectric layer 141 have a rounded shape. The first dielectric layer 141 surrounds the side of the first bonding pad 142 and may be in contact with a portion of the side of the first bonding pad 142.

A portion of the side of the first bonding pad 142 is positioned within the substrate 110, and a remainder of the side of the first bonding pad 142 is positioned within the first dielectric layer 141. The first bonding pad 142 includes a first surface that is in contact with the through silicon via 114 and a second surface that is opposite to the first surface. In an embodiment, the first and second surfaces have a flat shape in a horizontal cross-section. The level of the second surface of the first bonding pads 142 may be at the same as the level of the surface of the first dielectric layer 141 that faces away from the substrate 110. In an embodiment, the first bonding pad 142 has a rounded side shape. In an embodiment, the first bonding pad 142 has a circular or oval shape in the cross-section in the horizontal direction.

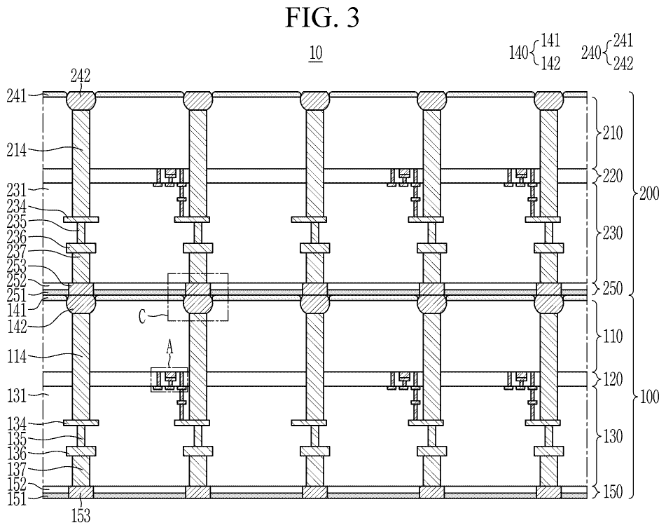

FIG. 3 is a cross-sectional view showing a first semiconductor stacking structure 10 of an embodiment.

Referring to FIG. 3, a first semiconductor stacking structure 10 includes a first semiconductor die 100 and a second semiconductor die 200. The first semiconductor die 100 and the second semiconductor die 200 may be the same type of semiconductor die. The second semiconductor die 200 includes the same configuration shown in FIG. 1 as the first semiconductor die 100. In an embodiment, the first semiconductor die 100 and the second semiconductor die 200 may each be a DRAM.

The first back side bonding structure 140 of the first semiconductor die 100 is bonded to the second front side bonding structure 250 of the second semiconductor die 200 by a hybrid bonding.

The first dielectric layer 141 of the first back side bonding structure 140 of the first semiconductor die 100 and the second dielectric layer 251 of the second front side bonding structure 250 of the second semiconductor die 200 are directly bonded by a nonmetal-nonmetal hybrid bonding. At the interface between the first dielectric layer 141 and the second dielectric layer 251, a covalent bond is formed by heat and pressure during the hybrid bonding process. The first dielectric layer 141 and the second dielectric layer 251 are composed of the same material, so after the hybrid bonding, the interface between the first dielectric layer 141 and the second dielectric layer 251 may disappear.

The first bonding pads 142 of the first back side bonding structure 140 of the first semiconductor die 100 and the second bonding pads 253 of the second front side bonding structure 250 of the second semiconductor die 200 are directly bonded by the metal-metal hybrid bonding. At the interface between the first bonding pads 142 of the first back side bonding structure 140 and the second bonding pads 253 of the second front side bonding structure 250, a metal b occurs by heat and pressure during the bonding process. The first bonding pads 142 of the first back side bonding structure 140 and the second bonding pads 253 of the second front side bonding structure 250 are composed of the same material, and after the hybrid bonding, the interface may disappear between the first bonding pads 142 of the first back side bonding structure 140 and the second bonding pads 253 of the second front side bonding structure 250. The first semiconductor die 100 and the second semiconductor die 200 are electrically connected to each other through the first bonding pads 142 of the first back side bonding structure 140 and the second bonding pads 253 of the second front side bonding structure 250.

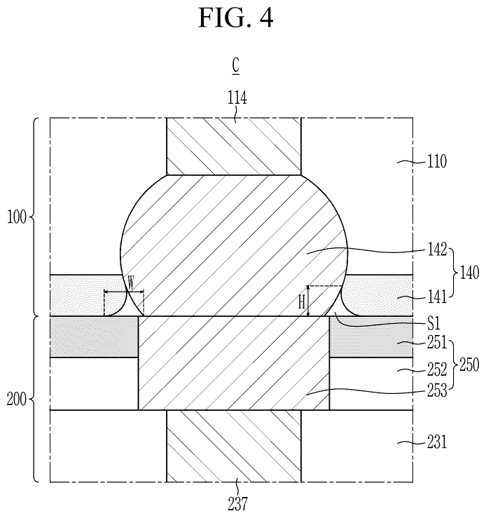

FIG. 4 is a cross-sectional view showing a region C of an embodiment of a first semiconductor stacking structure 10 in FIG. 3.

The hybrid bonding should be performed with the bonding surface of the first back side bonding structure 140 and the bonding surface of the second front side bonding structure 250 being flat. However, if the hybrid bonding is performed in a state where the bonding surface of the first back side bonding structure 140 and the bonding surface of the second front side bonding structure 250 are not flat due to a surface topography deviation, or process technology problems, the vertical lines of the first bonding pads 142 and the second bonding pads 253 that are bonded to each other will not match.

When a mismatch in the vertical lines of bonding pads occurs, the bonding surface of the bonding pads are misaligned which could result in the bonding pads contacting a dielectric layer. Additionally, the mismatch may result in portions of the bonding pads contacting a dielectric layer do not bond to the dielectric layer and cracks may occur in the interface between the bonding pads and the dielectric layer. In addition, during the bonding process, the edges of the dielectric layers may be broken due to the contact and impact between the bonding pads and the second dielectric layers.

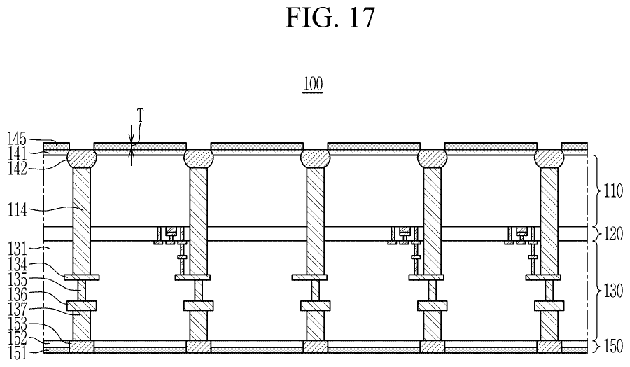

Referring to FIG. 4, according to embodiments of the inventive concept, since the first dielectric layer 141 include an edge portion that is oblique around the first bonding pad 142 and the first bonding pad 142 includes the rounded side shape, an air space S1 is formed at the interface of the first back side bonding structure 140 and the second front side bonding structure 250. The air space S1 is defined by the edge portion of the first dielectric layer 141, the surface of the second dielectric layer 251 facing the first dielectric layer 141, the surface of the second bonding pad 253 of the second front side bonding structure 250 facing the first dielectric layer 141, and the side of the first bonding pad 142 of the first back side bonding structure 140. The air space S1 has a width W in the horizontal direction and a height H in the vertical direction. The values of the width W and the height H of the air space S1 may be controlled by adjusting the thickness T in the vertical direction of the fourth dielectric layer (145, referring to FIG. 17) used when performing an angling process such as a chamfer process. The values of the width W and the height H of the air space S1 may be determined independently.

As described above, by forming the air spaces S1, when performing the hybrid bonding, the air spaces S1 prevent the dielectric layers from contacting the bonding pads due to the mismatch between the vertical lines of the bonding surfaces of the first bonding pads 142 of the first back side bonding structure 140 and the second bonding pads 253 of the second front side bonding structure 250. Accordingly, in the process of performing the bonding process, cracks may be prevented and/or the edge of the first dielectric layer 141 and the edge of the second dielectric layer 251 may be prevented from breaking which otherwise may occur due to contact between the first bonding pads 142 and the second dielectric layer 251, and between the second bonding pads 253 and the first dielectric layer 141, thereby improving the reliability.

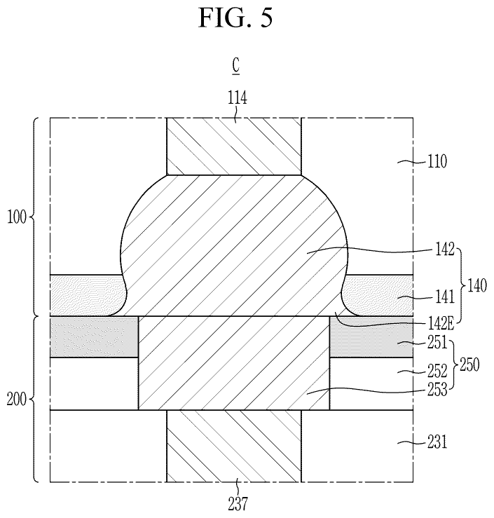

FIG. 5 is a cross-sectional view of a region C of another embodiment of a first semiconductor stacking structure 10 of FIG. 3.

Referring to FIG. 5, the first bonding pad 142 of first back side bonding structure 140 includes an extension 142E that fills the space corresponding to the air space S1 of FIG. 4 and extends to the edge portion of the first dielectric layer 141 of the first back side bonding structure 140. The extension 142E may be formed during the hybrid bonding process. For example, in the process of performing the hybrid bonding process, for bonding the first bonding pads 142 and the second bonding pads 253, as a heat treatment is performed on the first bonding pads 142 and the second bonding pads 253, the first bonding pads 142 of the first back side bonding structure 140 extends to (e.g., may flow into) the space corresponding to the air spaces S1 of FIG. 4. As a result, the bonding surface of the first bonding pads 142 of the first back side bonding structure 140 may be expanded, so that a design margin to match the vertical lines of the bonding surface of the first bonding pads 142 of the first back side bonding structure 140 and the bonding surface of the second bonding pads 253 of the second front side bonding structure 250 may be improved.

According to the embodiment of FIG. 5, the first bonding pad 142 is shown and described to be extended to the edge portion of the first dielectric layer 141 of the first back side bonding structure 140, but it is not limited thereto and the first bonding pad 142 may fill only a part of the space corresponding to the air space S1 of FIG. 4.

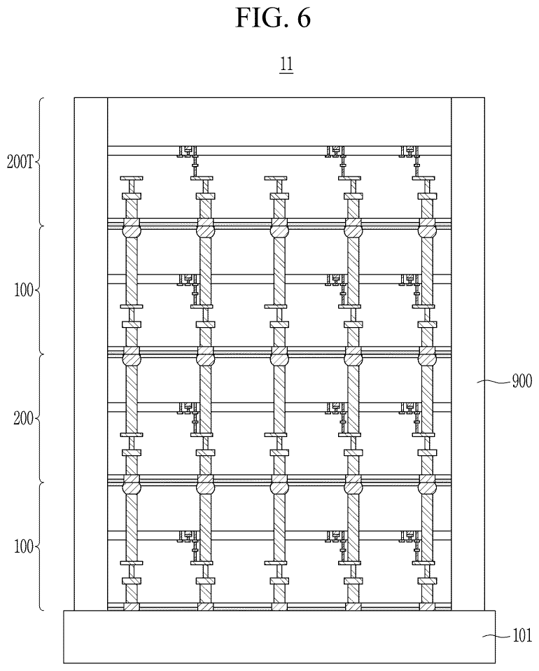

FIG. 6 is a cross-sectional view showing a semiconductor package 11 of an embodiment.

Referring to FIG. 6, a semiconductor package 11 includes a plurality of semiconductor stacking structures such as the semiconductor stacking structure 10 of FIG. 3. The semiconductor package 11 has a structure in which the first semiconductor dies 100 and the second semiconductor dies 200 are stacked alternately. The semiconductor package 11 may have a structure in which the same type of dies are stacked or different types of dies may be stacked when they have the configuration shown in FIG. 1. In an embodiment, the semiconductor package 11 may include high bandwidth memory (HBM).

The high-bandwidth memory (HBM) is a high-performance three-dimensional (3D) stacked dynamic random access memory (DRAM). The high-bandwidth memory (HBM) is manufactured by vertically stacking memory dies by performing a hybrid bonding or using micro bumps to form a single memory stack. The high-bandwidth memory (HBM) is equipped with multiple memory channels through a memory stack in which memory dies are stacked vertically, thereby enabling simultaneous implementation of lower latency and higher bandwidth compared to conventional DRAM products, and reducing the total area occupied by individual DRAMs on a printed circuit board (PCB), which is advantageous for high bandwidth compared to an area and has a merit of reducing power consumption.

The high bandwidth memory (HBM) includes a buffer die 101, first semiconductor dies 100, second semiconductor dies 200, and molding material 900.

The buffer die 101 may be positioned at the bottom of the high bandwidth memory (HBM). When transmitting and receiving data between devices with different data processing speeds, processing units, and usage times, data loss may occur due to differences in data processing speeds, processing units, and usage times between each device. To prevent this loss, the buffer die 101 temporarily saves information when sending and receiving a data between the first semiconductor die 100 and an external device (not shown) and between the second semiconductor die 200 and an external device (not shown). When transmitting a data to the first semiconductor dies 100 and the second semiconductor dies 200, or receiving a data from the first semiconductor dies 100 and the second semiconductor dies 200, the buffer die 101 matches the order of the data and passes the data sequentially.

The first semiconductor dies 100 and the second semiconductor dies 200 are positioned on the buffer die 101. A second semiconductor die 200T that does not have through silicon vias is positioned at the top of the memory stack. The first semiconductor die 100 is bonded to the buffer die 101 by the hybrid bonding process as described previously. The first semiconductor dies 100 and the second semiconductor dies 200 are bonded to each other by the hybrid bonding process as described previously. The hybrid bonding processes may be performed sequentially or at the same time.

The molding material 900 is positioned on the buffer die 101 and molds around the first semiconductor dies 100 and the second semiconductor dies 200. The molding material 900 serves to protect and insulate the first semiconductor dies 100 and the second semiconductor dies 200. In an embodiment, the molding material 900 may be formed of a thermosetting resin, such as epoxy resin. In an embodiment, the molding material 900 may be an epoxy molding compound (EMC).

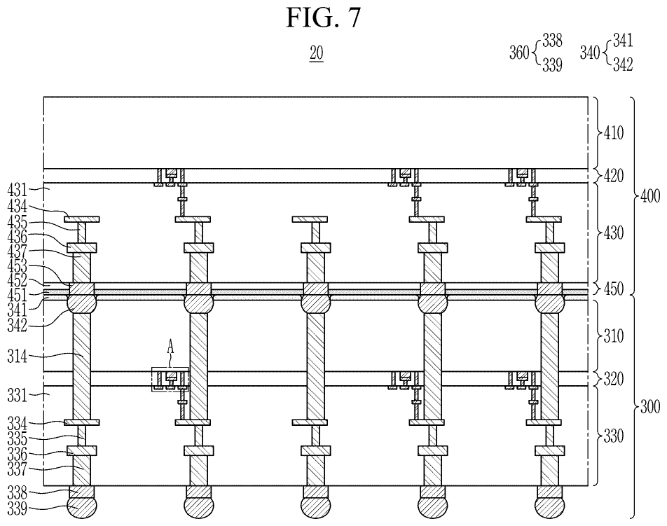

FIG. 7 is a cross-sectional view showing a second semiconductor stacking structure 20 of an embodiment. Details described regarding the region C of the first semiconductor stacking structure 10 of FIG. 4 and FIG. 5 may applied to the second semiconductor stacking structure 20 in the embodiment of FIG. 7.

Referring to FIG. 7, a second semiconductor stacking structure 20 includes a third semiconductor die 300 and a fourth semiconductor die 400. The third semiconductor die 300 and the fourth semiconductor die 400 are different types of dies. In an embodiment, the third semiconductor die 300 may include a central processing unit (CPU), or a graphic processing unit (GPU). In an embodiment, the fourth semiconductor die 400 may include at least one of a memory, a communication chip, a controller, or a sensor.

The third semiconductor die 300 includes a connection structure 360 to be connected to other devices. The connection structure 360 includes connection pads 338 and connection members 339. In an embodiment, the connection members 339 may include micro bumps. In one embodiment, the fourth semiconductor die 400 may not include through silicon vias extending from the front side to the back side of the substrate 410. In an embodiment, the fourth semiconductor die 400 may not include a back side bonding structure. The configuration of the third semiconductor die 300 and the fourth semiconductor die 400 may be the same as the first semiconductor die as described previously other than the differences described above.

The third back side bonding structure 340 of the third semiconductor die 300 is bonded to the fourth front side bonding structure 450 of the fourth semiconductor die 400 by hybrid bonding.

The first dielectric layer 341 of the third back side bonding structure 340 of the third semiconductor die 300 and the second dielectric layer 451 of the fourth front side bonding structure 450 of the fourth semiconductor die 400 are directly bonded by a nonmetal-nonmetal hybrid bonding. At the interface between the first dielectric layer 341 and the second dielectric layer 451, a covalent bond is formed by heat and pressure. The first dielectric layer 341 and the second dielectric layer 451 are composed of the same material, so after hybrid bonding, the interface between the first dielectric layer 341 and the second dielectric layer 451 may disappear.

The first bonding pads 342 of the third back side bonding structure 340 of the third semiconductor die 300 and the second bonding pads 453 of the fourth front side bonding structure 450 of the fourth semiconductor die 400 are directly bonded by a metal-metal hybrid bonding. At the interface between the first bonding pads 342 of the third back side bonding structure 340 and the second bonding pads 453 of the fourth front side bonding structure 450, a metal bonding occurs by heat and pressure. The first bonding pads 342 of the third back side bonding structure 340 and the second bonding pads 453 of the fourth front side bonding structure 450 are composed of the same material, and after hybrid bonding, the interface may disappear between the first bonding pads 342 of the third back side bonding structure 340 and the second bonding pads 453 of the fourth front side bonding structure 450. The third semiconductor die 300 and the fourth semiconductor die 400 are electrically connected to each other through the first bonding pads 342 of the third back side bonding structure 340 and the second bonding pads 453 of the fourth front side bonding structure 450.

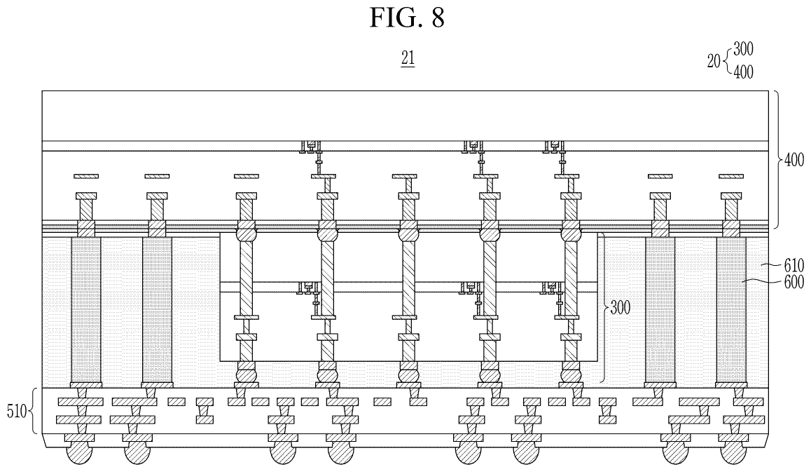

FIG. 8 is a cross-sectional view showing a semiconductor package 21 according to another embodiment.

Referring to FIG. 8, the semiconductor package 21 includes a redistribution layer structure 510, a semiconductor stacking structure 20 on the redistribution layer structure 510, conductive posts 600 on the redistribution layer structure 510, and a molding material 610 of molding the third semiconductor die 300 on the redistribution layer structure 510. The semiconductor stacking structure 20 includes a third semiconductor die 300 and a fourth semiconductor die 400. The footprint of the third semiconductor die 300 is included within the footprint of the fourth semiconductor die 400. The fourth semiconductor die 400 has a larger area than the third semiconductor die 300 in the horizontal direction. The third semiconductor die 300 is a different type of die than the fourth semiconductor die 400. The semiconductor package 21 has a structure in which different types of dies are stacked. In an embodiment, the semiconductor package 21 may include a system on chip (SoC). In an embodiment, the semiconductor package 21 may include a 3-dimensional integrated circuit (3DIC). In an embodiment, the third semiconductor die 300 may be a bottom die of the 3DIC. In an embodiment, the fourth semiconductor die 400 may be a top die of the 3DIC.

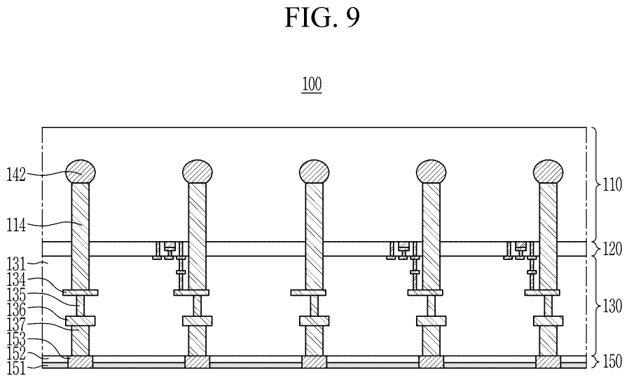

FIG. 9 to FIG. 18 are cross-sectional views to explain a method of manufacturing a first semiconductor die 100.

FIG. 9 is a cross-sectional view showing a steps of providing the first semiconductor die 100 in which through silicon vias 114 and first bonding pads 142 are formed.

Conventionally, first bonding pads are formed in the semiconductor back end process, but according to the present disclosure, with fewer steps than forming the bonding pads in the semiconductor back end process, the bonding pads are formed in the semiconductor front end process, and the semiconductor die with the bonding pads formed is provided to the semiconductor back end process. As a result, the process of forming the bonding pads may be deleted from the semiconductor back end process, thereby reducing a process time (TAT) and a process complexity, and reducing manufacturing costs.

The process of forming the first bonding pads 142 and through silicon vias (TSV; 114) in the semiconductor front end process is described as follows. First, holes that pass from the front side to the back side of the substrate 110 are formed, and ball-shaped recesses are formed at the ends of the holes. After this, a first conductive material is filled in the recesses to form the first bonding pads 142, and the holes are filled with a second conductive material to form the through silicon vias (TSV; 114).

In an embodiment, the hole may be formed by a deep etching. In an embodiment, the hole may be formed by a laser. In one embodiment, the ball-shaped recess may be formed by a dry etching. In an embodiment, the holes of the through silicon vias (TSV; 114) may be filled with a first conductive material by an electrolytic plating. In one embodiment, the holes in the through silicon vias (TSV; 114) may be filled with a first conductive material by a physical vapor deposition (PVD). In one embodiment, the ball-shaped recess may be filled with a second conductive material by an electrolytic plating. In one embodiment, the ball-shaped recess may be filled with a second conductive material by a physical vapor deposition (PVD).

In an embodiment, the first conductive material may be formed of and/or include at least one of tungsten, aluminum, copper, or alloys thereof. Also, a barrier layer (not shown) may be formed between the through silicon vias (TSV; 114), and the substrate 110, the activation layer 120, and an insulating material of the wire layer 130. In an embodiment, the barrier layer (not shown) may be formed of and/or include at least one of titanium, tantalum, titanium nitride, tantalum nitride, or alloys thereof. In an embodiment, the second conductive material may be formed of and/or include copper. In an embodiment, the second conductive material may be a conductive material capable of applying hybrid bonding.

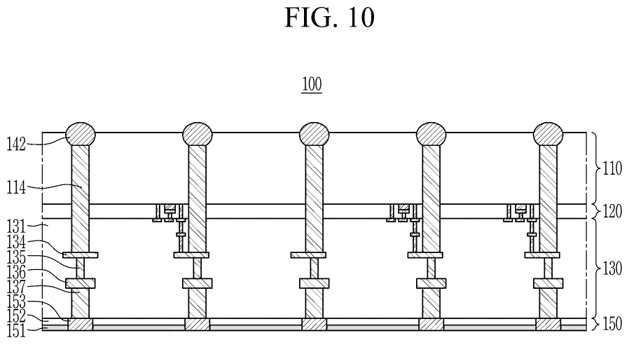

FIG. 10 is a cross-sectional view showing a step of partially exposing a first bonding pads 142.

Referring to FIG. 10, the back side of the substrate 110 is etched to expose a portion of the surface of each first bonding pad 142 among the first bonding pads 142. In one embodiment, the process of etching the back side surface of the substrate 110 may be performed by a dry etching.

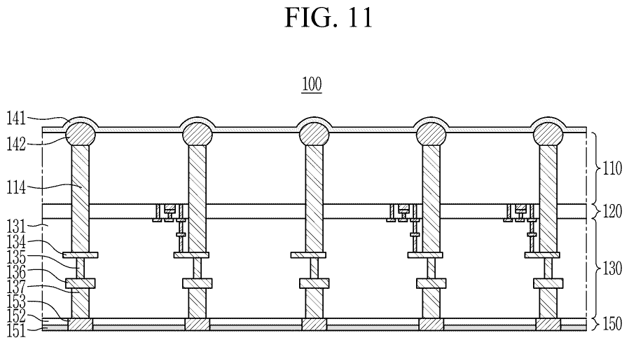

FIG. 11 is a cross-sectional view showing a step of forming a first dielectric layer 141 on the exposed surface of the first bonding pads 142 and the exposed surface of the substrate 110.

Referring to FIG. 11, the first dielectric layer 141 is formed on the exposed surface of the first bonding pads 142 and the exposed surface of the substrate 110. In an embodiment, the first dielectric layer 141 may be formed through an atomic layer deposition (ALD) process or a chemical vapor deposition (CVD) process.

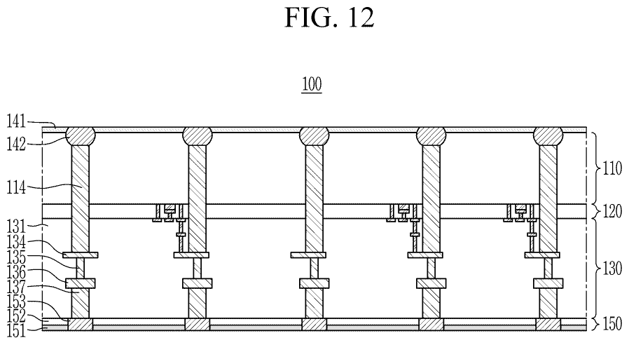

FIG. 12 is a cross-sectional view showing a step of performing a planarization process on the first dielectric layer 141 and the first bonding pads 142.

Referring to FIG. 12, a chemical mechanical polishing (CMP) is performed to level the upper surfaces of the first dielectric layer 141 and the first bonding pads 142. By applying the CMP process, the upper surfaces of the first dielectric layer 141 and the first bonding pads 142 may be planarized.

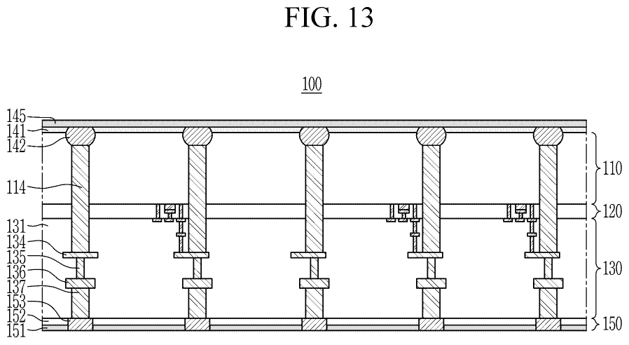

FIG. 13 is a cross-sectional view showing a step of forming a fourth dielectric layer 145 on the planarized first dielectric layer 141 and first bonding pads 142.

Referring to FIG. 13, the fourth dielectric layer 145 is formed on the planarized first dielectric layer 141 and first bonding pads 142. In an embodiment, the fourth dielectric layer 145 may be formed through an atomic layer deposition (ALD) process or a chemical vapor deposition (CVD) process.

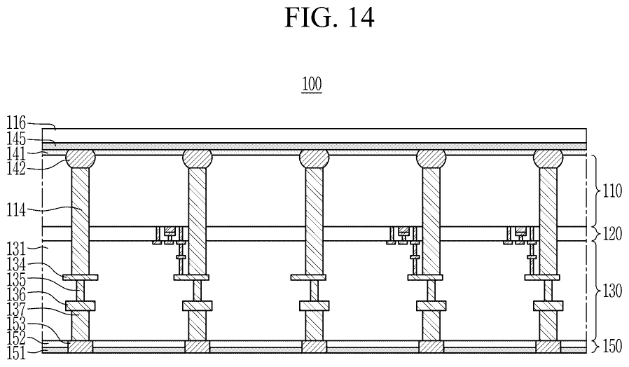

FIG. 14 is a cross-sectional view showing a step of forming a photoresist 116 on the fourth dielectric layer 145.

Referring to FIG. 14, the photoresist 116 is formed on the fourth dielectric layer 145. In an embodiment, the photoresist 116 may be formed through a spin coating. In one embodiment, the photoresist 116 may include an organic polymer resin including a photosensitivity (photoactive) material.

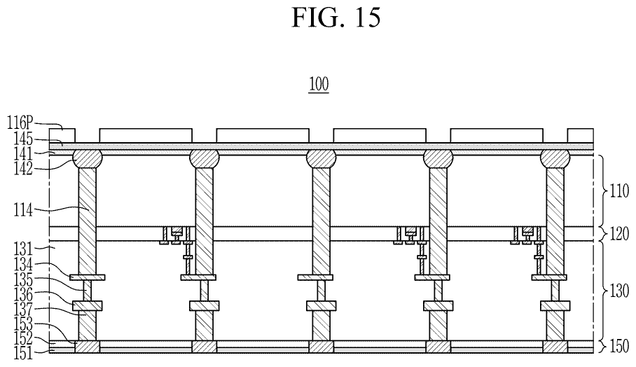

FIG. 15 is a cross-sectional view showing a step of forming a photoresist pattern 116P by exposing and developing the photoresist 116.

Referring to FIG. 15, the photoresist 116 is exposed and developed to form the photoresist pattern 116P.

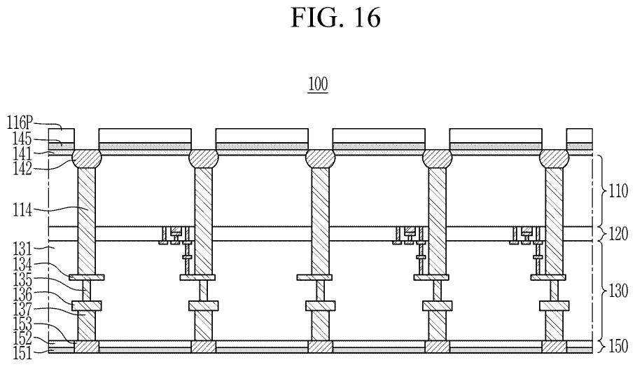

FIG. 16 is a cross-sectional view showing a step of exposing bonding surfaces of first bonding pads 142 by forming a pattern in a fourth dielectric layer 145.

Referring to FIG. 16, the fourth dielectric layer 145 exposed from the photoresist pattern 116P is etched to expose the planarized bonding surfaces of the first bonding pads 142. In one embodiment, the process of etching the fourth dielectric layer 145 may be performed by a dry etching.

FIG. 17 is a cross-sectional view showing a step of removing a photoresist pattern 116P.

Referring to FIG. 17, the photoresist pattern 116P is removed. In an embodiment, the photoresist pattern 116P may be removed by at least one of etching, ashing, or stripping.

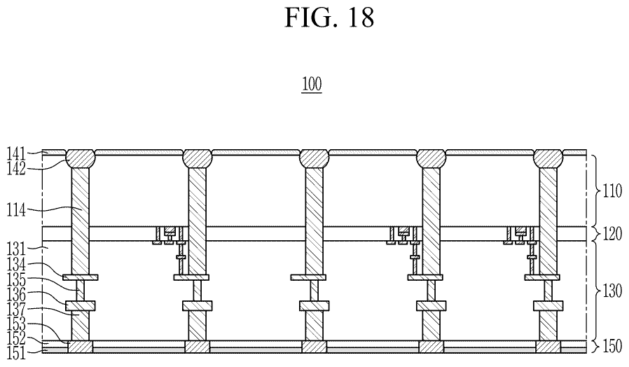

FIG. 18 is a cross-sectional view showing a step of removing the remaining fourth dielectric layer 145 and performing an angling process, such as a chamfering process, on the first dielectric layer 141 around the first bonding pad 142.

Referring to FIG. 18, the remaining fourth dielectric layer 145 is removed and an angling process, such as a chamfering process, is performed on the first dielectric layer 141 around the first bonding pad 142. In an embodiment, the process of removing the remaining fourth dielectric layer 145 and the process of performing the angling process on the first dielectric layer 141 around the first bonding pad 142 may be a wet etching. In an embodiment, the process of removing the remaining fourth dielectric layer 145 and the process of performing the angling process on the first dielectric layer 141 around the first bonding pad 142 may be simultaneously performed by a single etching process.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A semiconductor package comprising:
a first semiconductor die including a back side bonding structure; and
a second semiconductor die including a front side bonding structure bonded to the back side bonding structure,
wherein the back side bonding structure includes
a first dielectric layer; and
first bonding pads passing through the first dielectric layer, the front side bonding structure includes
a second dielectric layer bonded to the first dielectric layer; and
second bonding pads with each second bonding pad bonded to a respective first bonding pad and passing through the second dielectric layer, and
wherein the first dielectric layer includes oblique edge portions around the first bonding pads at a surface facing the second dielectric layer.

2. The semiconductor package of claim 1, wherein:
each oblique edge portion of the oblique edge portions is rounded.

3. The semiconductor package of claim 1, wherein:
each first bonding pad of the first bonding pads includes a rounded side.

4. The semiconductor package of claim 1, further comprising:
air spaces,
wherein each air space of the air spaces is defined by the oblique edge portion of the first dielectric layer, the surface of the second dielectric layer facing the first dielectric layer, the surface of each second bonding pad facing the first dielectric layer among the second bonding pads, and the side of each first bonding pad among the first bonding pads.

5. The semiconductor package of claim 1, wherein:
each first bonding pad among the first bonding pads extends to a corresponding oblique edge portion among the oblique edge portions.

6. The semiconductor package of claim 1, wherein:
the first dielectric layer is directly bonded to the second dielectric layer.

7. The semiconductor package of claim 1, wherein:
the first dielectric layer and the second dielectric layer each include silicon nitride.

8. The semiconductor package of claim 1, wherein:
each first bonding pad among the first bonding pads is directly bonded to a corresponding second bonding pad among the second bonding pads.

9. A semiconductor package comprising:
a first semiconductor die and a second semiconductor die,
wherein the first semiconductor die includes:
a first substrate;
through silicon vias extending from a front side of the first substrate to a back side of the first substrate; and
a back side bonding structure positioned on the back side of the first substrate,
the second semiconductor die includes:
a second substrate;
a wire layer positioned on the front side of the second substrate; and
a front side bonding structure positioned on the wire layer and bonded to the back side bonding structure,
the back side bonding structure includes:
a first dielectric layer; and
first bonding pads passing through the first dielectric layer, wherein each first bonding pad of the first bonding pads is in contact with a through silicon via among the through silicon vias, and
the front side bonding structure includes:
a second dielectric layer bonded to the first dielectric layer; and
second bonding pads with each second bonding pad bonded to a respective first bonding pad and passing through the second dielectric layer,
wherein the first dielectric layer includes oblique edge portions around the first bonding pads at a surface facing the second dielectric layer.

10. The semiconductor package of claim 9, wherein:
the front side bonding structure further includes a third dielectric layer under the second dielectric layer, and
the second bonding pads passes through the third dielectric layer.

11. The semiconductor package of claim 9, wherein:
the first semiconductor die is the same type of die as the second semiconductor die.

12. The semiconductor package of claim 11, wherein:
the first semiconductor die and the second semiconductor die are each a dynamic random access memory die.

13. The semiconductor package of claim 9, wherein:
the first semiconductor die is a different type of die than the second semiconductor die.

14. The semiconductor package of claim 13, wherein:
the first semiconductor die is a bottom die of a 3D integrated circuit, and
the second semiconductor die is a top die of the 3D integrated circuit.

15. The semiconductor package of claim 14, wherein:
the 3D integrated circuit comprises a system on chip (SoC).

16. A manufacturing method of a semiconductor package comprising:
forming through silicon vias within a semiconductor die, wherein the through silicon vias extend from a front side to a back side of a substrate of the semiconductor die;
forming ball-shaped bonding pads in first ends of the through silicon vias;
exposing the bonding pads by etching a back side surface of the substrate;
forming a first dielectric layer on the exposed bonding pads and the etched back side of the substrate;
performing a planarization process on the bonding pads and the first dielectric layer;
forming a second dielectric layer on the planarized first bonding pads and the first dielectric layer;
forming a pattern on the second dielectric layer exposing an upper surface of the planarized first bonding pads; and
etching the pattern on the second dielectric layer and performing a chamfering process on the first dielectric layer around the first bonding pads.

17. The manufacturing method of claim 16, wherein:
etching the pattern of the second dielectric layer and performing a chamfering process on the first dielectric layer around the first bonding pads are simultaneously performed by a single etching process.

18. The manufacturing method of claim 17, wherein:
the single etching process is a wet etching process.

19. The manufacturing method of claim 16, wherein:
forming the pattern on the second dielectric layer comprises;
forming a photoresist pattern on the second dielectric layer; and
etching the second dielectric layer exposed by the photoresist pattern to expose the upper surface of the planarized first bonding pads.

20. The manufacturing method of claim 19, wherein:
etching the second dielectric layer exposed from the photoresist pattern is performed by a dry etching process.
